(19) United States
(12) Patent Application Publication
(10) Pub. No.: US 2026/0333859 A1
(43) Pub. Date: Oct. 22, 2026

(54) SOURCE/DRAIN REGIONS AND CONTACT PLUGS IN STACKING TRANSISTORS AND METHODS OF FORMING THE SAME

(71) Applicant: Taiwan Semiconductor Manufacturing Co., Ltd., Hsinchu (TW)

(72) Inventors: Tzu Pei Chen, Taipei (TW); Yuting Cheng, Taoyuan (TW); Meng-Hsi Chuang, Hsinchu (TW); Olivia Pei-Hua Lee, Hsinchu (TW); Kuan-Kan Hu, Hsinchu (TW); Sung-Li Wang, Zhubei (TW); Pinyen Lin, Rochester, NY (US)

(21) Appl. No.: 19/727,828

(22) Filed: Jul. 1, 2026

Related U.S. Application Data
(63) Continuation of application No. 19/065,811, filed on Feb. 27, 2025.
(60) Provisional application No. 63/711,941, filed on Oct. 25, 2024.

(51) Int. Cl. H10D 84/85; H10D 30/00; H10D 30/01; H10D 62/10; H10D 62/13; H10D 62/80; H10D 64/23; H10D 84/01

(52) U.S. Cl. CPC H10D 84/851; H10D 30/019; H10D 30/502; H10D 62/121; H10D 62/151; H10D 62/882; H10D 64/254; H10D 64/256; H10D 84/017; H10D 84/0186; H10D 84/856

(57) ABSTRACT

A method includes patterning a first opening through a first dielectric layer to expose a first source/drain region; forming a first silicide region on the first source/drain region; depositing a first plurality of polycyclic aromatic hydrocarbons along surfaces of the first opening; performing an annealing process to convert the first plurality of polycyclic aromatic hydrocarbons into a first graphene layer; and filling a remainder of the first opening with a first metal material. In another embodiment, the method further includes forming a second opening through the first dielectric layer, a second source/drain region, and a third dielectric layer to expose a third source/drain region, wherein in a top-down view the second source/drain region overlaps the third source/drain region.

### PRIORITY CLAIM AND CROSS-REFERENCE

This application is a continuation of U.S. patent application Ser. No. 19/065,811 filed on Feb. 27, 2025, which application claims the benefit of the following provisionally filed U.S. Patent Application No. 63/711,941, filed on Oct. 25, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3, 4A, 4B, 5A, 5B, 6A, 6B, 7A, 7B, 8A, 8B, 9A, 9B, 10A, 10B, 11A, and 11B are views of intermediate stages in the manufacturing of stacking transistors, in accordance with some embodiments.

FIG. 12 is a view of an intermediate stage in the manufacturing of stacking transistors, in accordance with some embodiments.

FIGS. 13 through 16 are views of intermediate stages in the manufacturing of stacking transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure and the method of forming the same are provided. Stacking transistor structures, such as CFETs, and the method of forming the same are provided. The stacking transistor structure includes two transistors that are vertically stacked and that are of opposite types (e.g., an n-type transistor and a p-type transistor that are vertically stacked). As such, source/drain regions of vertically stacked transistors may also be vertically stacked. In addition, source/drain region contacts may be formed to the upper source/drain regions and/or the lower source/drain regions. Patterning steps may be used to form openings to the source/drain regions, and the openings to the lower source/drain regions may have high aspect ratios (e.g., up to 8 to 15). In various embodiments, a thin liner (e.g., an ultra thin liner of less than or equal to 5 Å) is formed along surfaces of the openings, and a remainder of the openings are filled with a conductive fill material. For example, the thin liner may include polycyclic aromatic hydrocarbons (PAHs), which may be treated and converted into a graphene liner layer before or after depositing the conductive fill material. As a result of the thin liner, the conductive fill material may be deposited into the openings (e.g., having high aspect ratios) without pinching or formation of voids. The source/drain contacts are formed with improved yield and reliability, which results in greater performance and robustness of the stacking transistors.

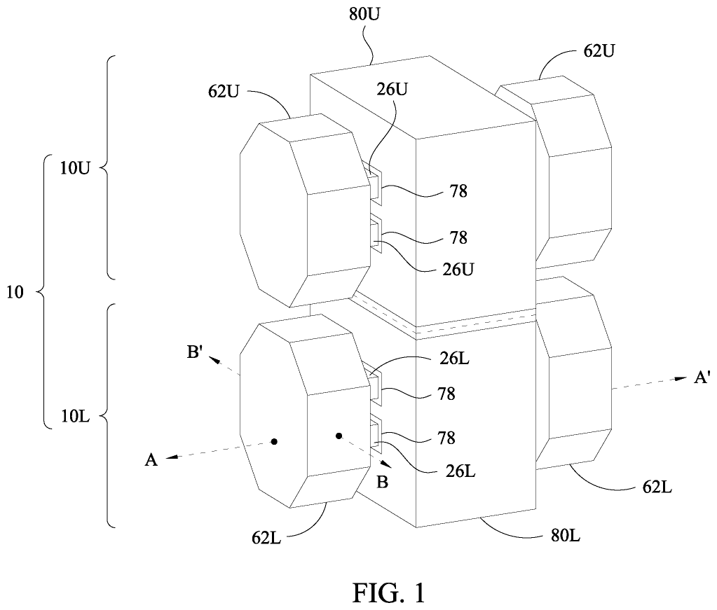

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Cross-section B-B′ is a vertical cross-section that is perpendicular to cross-section A-A′ and extends through the source/drain regions 62 of the stacking transistor. Subsequent figures may refer to these reference cross-sections for clarity.

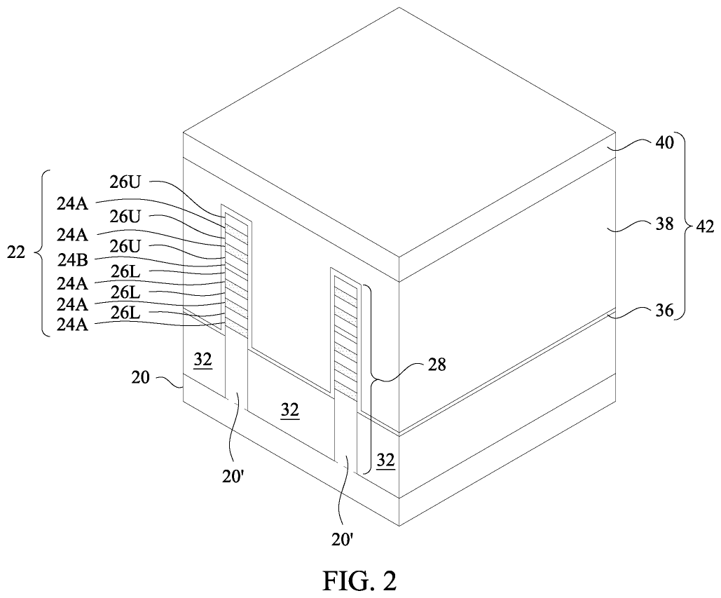

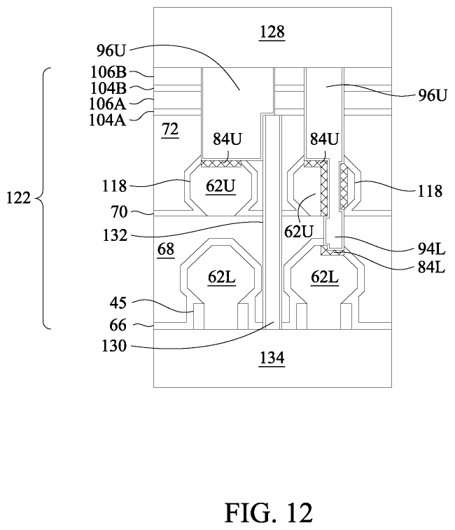

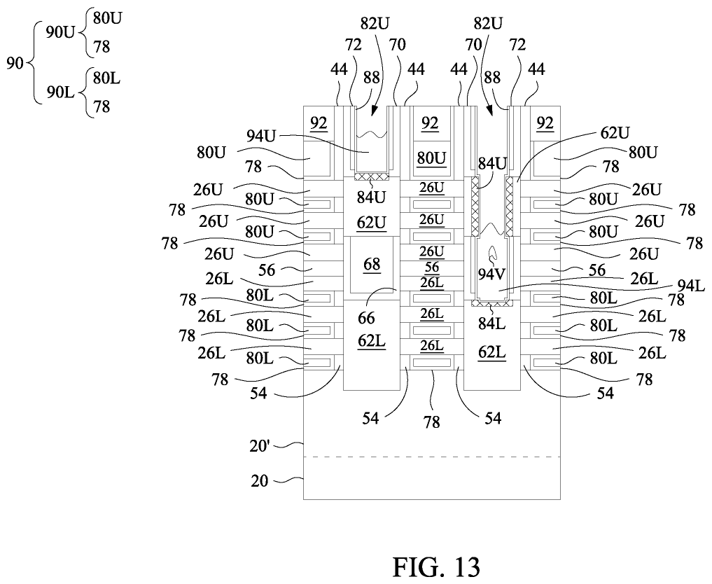

FIGS. 2 through 16 illustrate the cross-sectional views of intermediate stages in the formation of stacking transistors (as schematically represented in FIG. 1) in accordance with some embodiments. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the vertical cross-sectional views along a similar cross-section as the vertical reference cross-section B-B′ in FIG. 1. In addition, FIG. 12 illustrates the vertical cross-section B-B', and FIGS. 13 through 16 illustrate the vertical cross-section A-A′.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked components of the multi-layer stack 22 are referred to as nanostructures hereinafter. Specifically, the multi-layer stack 22 includes dummy nanostructures 24A, one or more dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32 such as shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) may be recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

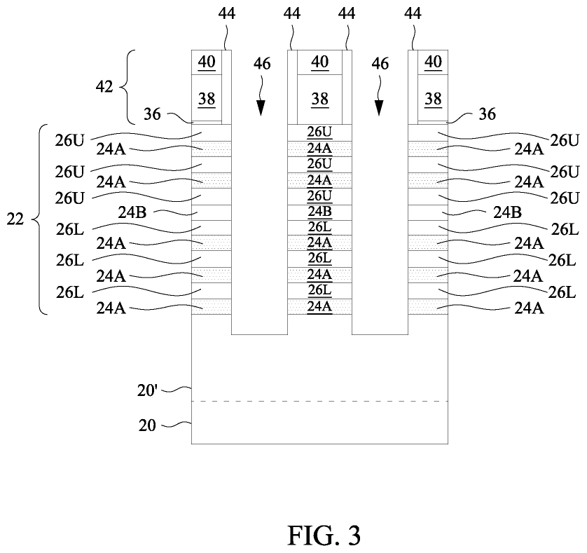

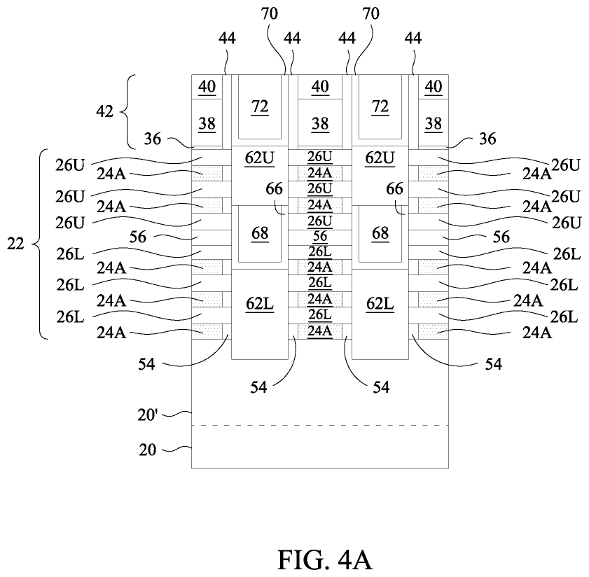

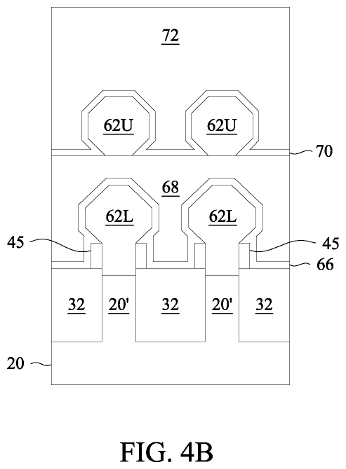

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 (see FIG. 4B) may also be formed as part of forming the gate spacers 44.

Subsequently, source/drain recesses 46 are formed in semiconductor strips 28. The source/drain recesses 46 are formed through etching, and may extend through the multi-layer stacks 22 and into the semiconductor strips 20′. Bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

FIGS. 4A and 4B illustrate various subsequent processing steps. FIG. 4A illustrates the A-A′ cross-section of the structure, and FIG. 4B illustrates the B-B′ cross-section of the structure. In particular, inner spacers 54 and dielectric isolation layers 56 are formed. Forming the inner spacers 54 and the dielectric isolation layers 56 may include an etching process that laterally etches the dummy nanostructures 24A and removes the dummy nanostructures 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

The inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As further illustrated by FIGS. 4A and 4B, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the second ILD 72.

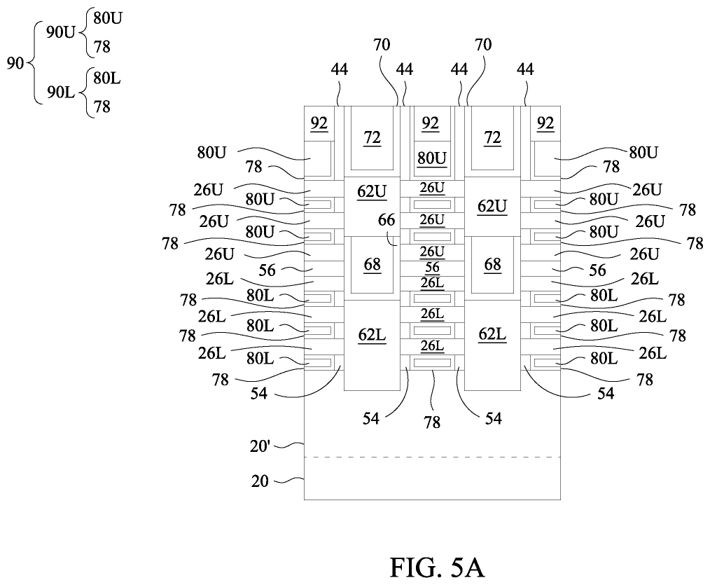

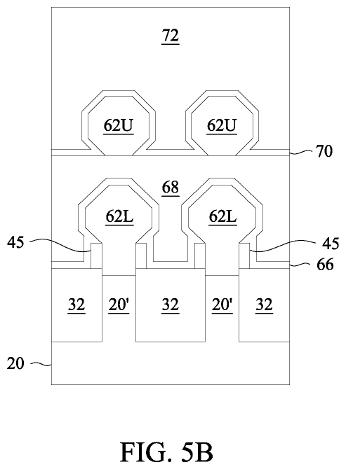

In FIGS. 5A and 5B, a replacement gate process is performed to replace the dummy gate stacks 42 and the dummy nanostructures 24A with gate stacks 90. FIG. 5A illustrates the A-A′ cross-section of the structure, and FIG. 5B illustrates the B-B′ cross-section of the structure. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the material of the dummy nanostructures 24A is etched at a faster rate than the materials of the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As further illustrated by FIG. 5A, gate masks 92 are formed over the gate stacks 90. The formation process may include recessing gate stacks 90, filling the resulting recesses with a dielectric material such as silicon nitride, silicon carbonitride, silicon oxynitride, silicon oxycarbonitride, the like, or a combination thereof, and performing a planarization process to remove the excess portions of the dielectric material over the second ILD 72.

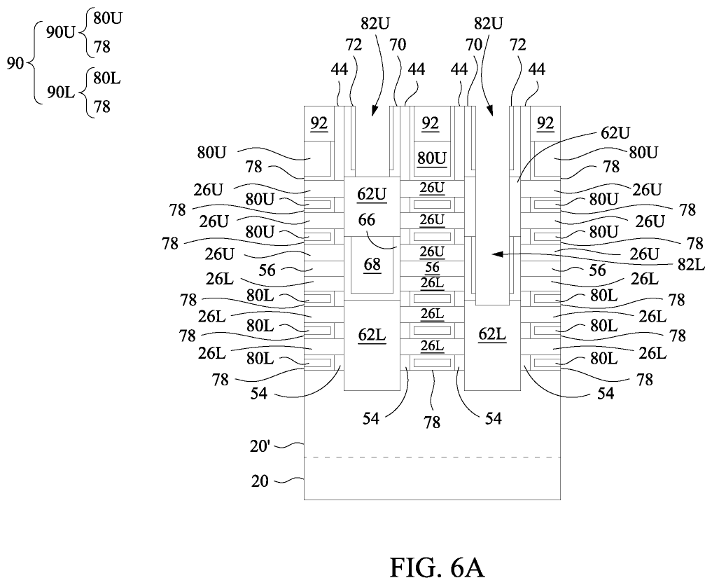

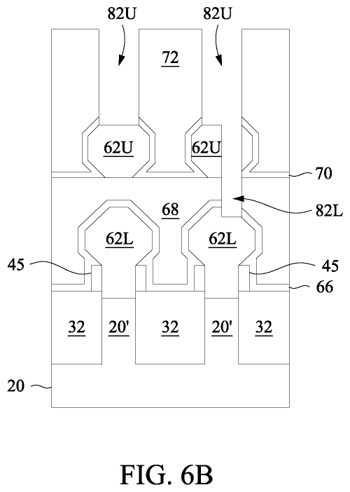

FIGS. 6A through 10B illustrate formation of source/drain contacts 96 (e.g., contact plugs) to electrically couple to the upper epitaxial source/drain regions 62U and/or the lower epitaxial source/drain regions 62L, in accordance with some embodiments. FIGS. 6A, 7A, 8A, 9A, and 10A illustrate the A-A′ cross-section of the structure, and FIGS. 6B, 7B, 8B, 9B, and 10B illustrate the B-B′ cross-section of the structure. As described in greater detail below, source/drain contact openings 82 are formed to the source/drain regions 62, a source/drain contact liner layer 88 is formed in the source/drain contact openings, and a remainder of the source/drain contact openings 82 is filled with a conductive material 94 to form the source/drain contacts 96.

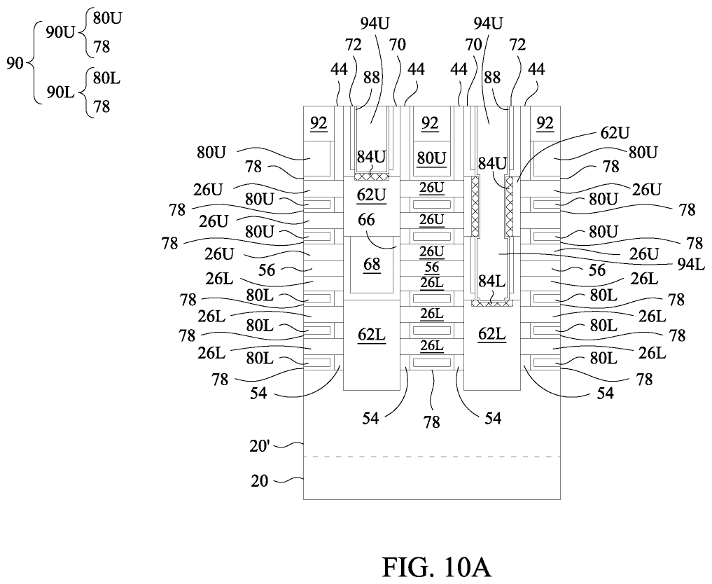

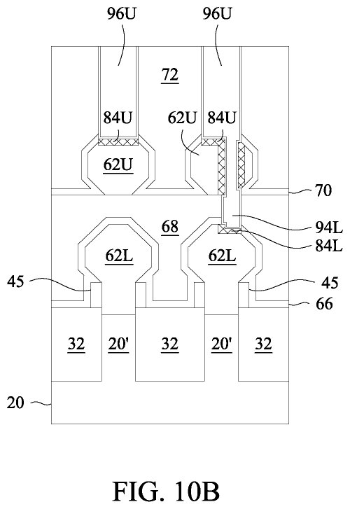

In FIGS. 6A and 6B, source/drain contact openings 82 are formed through the second ILD 72 to the upper epitaxial source/drain regions 62U and/or the lower epitaxial source/drain regions 62L. For example, upper source/drain contact openings 82U and lower source/drain contact openings 82L are formed to expose (and optionally extend into) the upper epitaxial source/drain regions 62U and/or the lower epitaxial source/drain regions 62L, respectively. Specifically, the lower source/drain contact openings 82L may extend through the second ILD 72, the second CESL 70, the upper epitaxial source/drain regions 62U, the first ILD 68, and/or the first CESL 66 to expose and extend partially into the lower epitaxial source/drain regions 62L, and the upper source/drain contact openings 82U extend through the second ILD 72 and the second CESL 70 to expose and extend partially into the upper epitaxial source/drain regions 62U. Each of the upper source/drain contact openings 82U may or may not be connected to one of the lower source/drain contact openings 82L. In areas where the upper and lower source/drain contact openings 82U and 82L are connected, the exposed upper and lower epitaxial source/drain regions 62U and 62L may be electrically connected together by source/drain contacts that are subsequently formed in the connected upper and lower source/drain contact openings 82U and 82L (see FIGS. 10A and 10B).

For example, the upper and lower source/drain contact openings 82U and 82L may be formed by a combination of sequential photolithography and etching processes. In some embodiments, the lower source/drain contact openings 82L may be formed prior to forming the upper source/drain contact openings 82U. Alternatively, this order may be reversed, and the upper source/drain contact openings 82U may be formed prior to forming the lower source/drain contact openings 82L.

In accordance with various embodiments, the source/drain contact openings 82 may have high aspect ratios. For example, the aspect ratios of the lower source/drain contact openings 82L may be up to about 8 to about 15. In addition, widths (e.g., diameters) of the source/drain contact openings 82 may be about 4 nm to about 15 nm. Moreover, the lower source/drain contact openings 82L may have depths ranging from about 32 nm to about 225 nm. For example, embodiments of the lower source/drain contact opening 82L with a width of about 4 nm may have a depth of between about 32 nm and about 60 nm (e.g., an aspect ratio ranging from 8 to 15). In addition, embodiments of the lower source/drain contact opening 82L with a width of about 15 nm may have a depth of between about 60 nm and about 225 nm (e.g., an aspect ratio ranging from 8 to 15).

In some embodiments (see FIG. 12), formation of the source/drain contact openings 82 may include a widening process to widen upper portions of the source/drain contact openings 82. For example, an over-etching in the upper portions may be used to decrease the aspect ratio for the upper portions of the source/drain contact openings 82. These wider upper portions may improve the gap-fill processes during formation of the source/drain contacts 82.

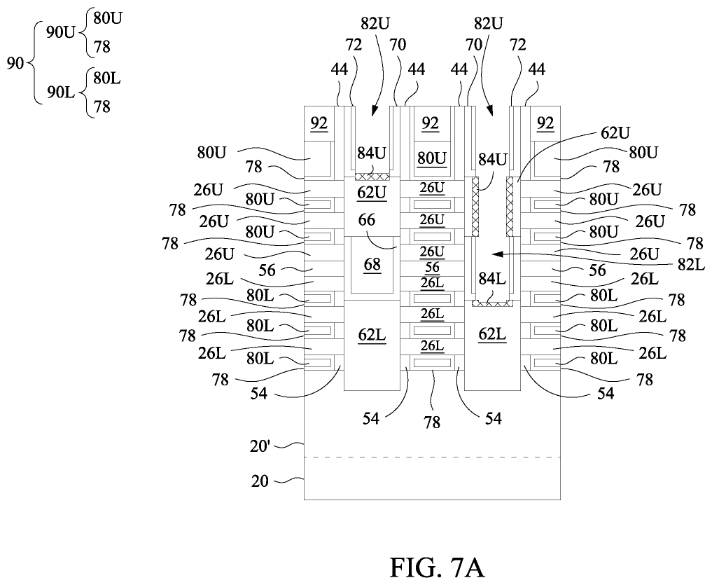

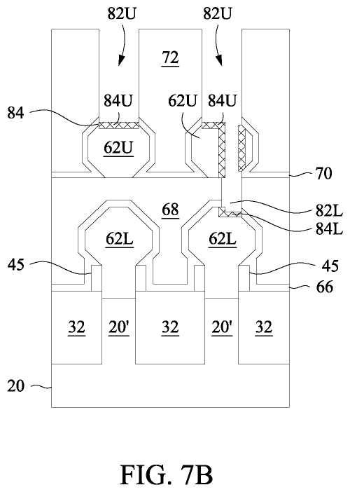

In FIGS. 7A and 7B, metal-semiconductor alloy regions 84 are formed at the interfaces between the source/drain regions 62 and the source/drain contacts 96. The metal-semiconductor alloy regions 84 can be silicide regions formed of a metal silicide (e.g., nickel silicide (NiSi), titanium silicide (TiSi), tungsten silicide (WSi), molybdenum silicide (MoSi), ruthenium silicide (RuSi), zirconium silicide (ZrSi), antimony silicide (SbSi), cobalt silicide (CoSi), etc.), germanide regions formed of a metal germanide (e.g. nickel germanide (NiGe), titanium germanide (TiGe), tungsten germanide (WGe), molybdenum germanide (MoGe), ruthenium germanide (RuGe), zirconium germanide (ZrGe), antimony germanide (SbGe), cobalt germanide (CoGe), etc.), silicon-germanide regions formed of both a metal silicide and a metal germanide, or the like. The metal-semiconductor alloy regions 84 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys.

In addition, the metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 84. The metal-semiconductor alloy regions 84 may include upper metal-semiconductor alloy regions 84U along exposed surfaces of the upper source/drain regions 62U and lower metal-semiconductor alloy regions 84L along exposed surfaces of the lower source/drain regions 62L.

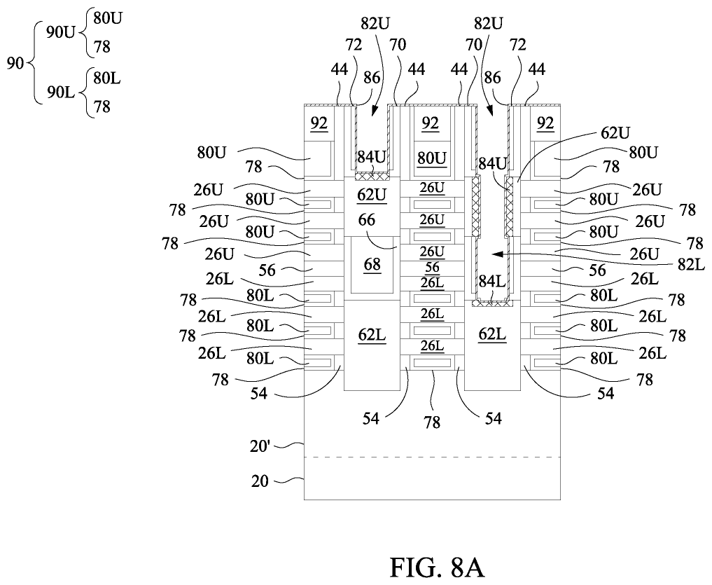

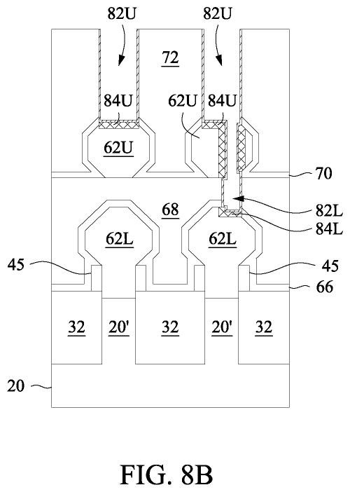

In FIGS. 8A and 8B, a contact liner precursor 86 is formed along surfaces of the source/drain contact openings 82. In some embodiments, forming the contact liner precursor 86 includes depositing a plurality of polycyclic aromatic hydrocarbons (PAHs) along the surfaces of the source/drain contact openings 82. The PAHs may include, for example, anthracene, pyrene, perylene, coronene, ovalene, benzocoronene, the like, or any combinations thereof. The contact liner precursor 86 may attach and adhere to the surfaces without forming chemical bonds. For example, the contact liner precursor 86 may adhere to the surfaces by electrostatic interactions, such as hydrogen bonding and/or van der Waals forces. For example, hydrogen bonding may adhere the contact liner precursor 86 to the first and second ILDs 68/72 and the first and second CESLs 66/70 of silicide, oxide, nitride, or the like by van der Waals forces (e.g., weak electrostatic forces). As such, an interface between the contact liner precursor 86 and the surfaces of the source/drain contact openings 82 (e.g., the metal-semiconductor alloy regions 84) may be substantially free of chemical bonds.

The deposition processes may be any suitable method such as thermal evaporation deposition. For example, a precursor material may be evaporated into a vapor in a vacuum chamber, sending the vapor through a gas line to a processing chamber, and condensing the vapor onto the structure (e.g., the surfaces of the source/drain contact openings 82. In some embodiments, the thermal evaporation deposition is performed at a temperature ranging from about 300 °C to about 400 °C.

In some embodiments, the contact liner precursor 86 within each source/drain contact opening 82 may have the form of small sheets (e.g., groupings or clusters) which are discontinuous or interconnected with a plurality of voids. For example, any of the PAHs listed above (or the like) may compose the contact liner precursor. In some embodiments, some or substantially all of the PAHs may be chemically bonded to one another to form a PAH network along the surfaces of the respective source/drain contact opening 82. As such, the contact liner precursor may have a thickness of less than or equal to about 10 Å, such as being less than or equal to about 5 Å.

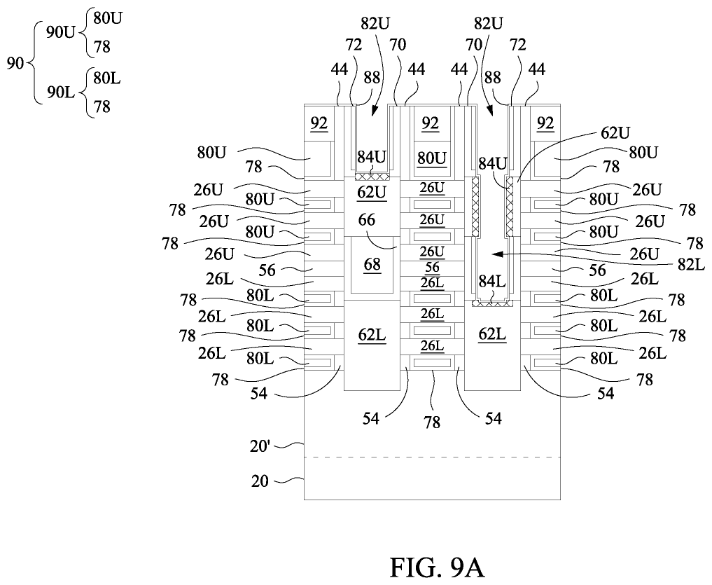

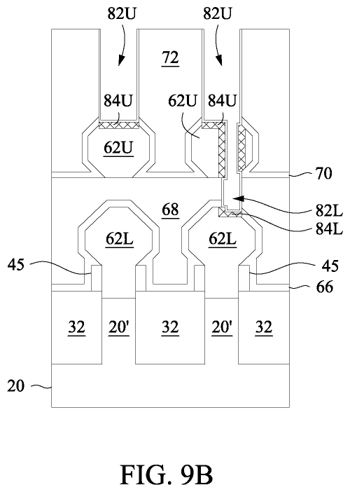

In FIGS. 9A and 9B, a treatment is performed to convert the contact liner precursor 86 to a contact liner layer 88. In some embodiments, the treatment may be an annealing process, such as a flash vacuum pyrolysis (FVP) annealing process. For example, the treatment may convert the contact liner precursor 86 comprising PAHs into the contact liner layer 88 comprising a graphene sheet (e.g., a two-dimensional (2D) layer which follows the contours of the source/drain contact opening 82). As a result, the contact liner layer 88 may have a thickness of less than or equal to 5 Å (e.g., ranging from about 3 Å to about 5 Å). Note that the increase of the aspect ratios of the source/drain contact openings 82 is small enough to benefit subsequent processes for filling remainders of the source/drain contact openings 82 with a conductive fill material.

In accordance with some embodiments, the FVP annealing process connects distinct PAH molecules (e.g., groupings or small sheets) to one another to form the contact liner layer 88 within each of the source/drain contact openings 82 into a substantially continuous sheet or several large continuous sheets. In embodiments in which the contact liner precursor 86 comprises a network of interconnected PAHs, the treatment may further connect the PAHs (e.g., filling voids) to form a graphene sheet. Each graphene sheet of the contact liner layer 88 may have few voids or substantially no voids. As such, the contact liner layer 88 includes a more orderly arrangement of aromatic rings as

### Compared to the Contact Liner Precursor 86.

The FVP annealing process may be performed at a temperature ranging from about 300 °C to about 1100 °C, at a pressure ranging from about 1E4 Torr to about 5 Torr, and for a duration of between about 0.1 seconds and about 5 seconds. For example, the FVP annealing process may be performed at a temperature greater than the temperature(s) used to deposit the contact liner precursor 86.

Similarly as discussed above with the contact liner precursor 86, van der Waals forces allow the contact liner layer 88 to adhere to the surfaces of the source/drain contact openings 82. As such, an interface between the contact liner layer 88 and the surfaces of the source/drain contact openings 82 (e.g., the metal-semiconductor alloy regions 84) may remain substantially free of chemical bonds.

In accordance with some embodiments (not specifically illustrated), the contact liner layer 88 may have varying thicknesses along the source/drain contact openings 82. For example, the contact liner precursor 86 may deposit with a greater thickness along the metal-semiconductor alloy regions 84 than along the dielectric layers (e.g., the CESL 66, the first ILD 68, the CESL 70, and/or the second ILD 72). In addition, the contact liner precursor 86 may deposit with a greater thickness over upward surfaces than over sidewall surfaces. As such, the contact liner precursor 86 may deposit with a greater thickness over the lower metal-semiconductor alloy regions 84L than over the sidewall surfaces of the upper metal-semiconductor alloy regions 84U. However, the contact liner precursor 86 may deposit with a greatest thickness over upward surfaces of the upper metal-semiconductor alloy regions 84U. These relative thickness variations in the contact liner precursor may remain substantially the same after formation of the contact liner layer 88. In other embodiments, the contact liner precursor 86 may deposit with a greater thickness over the dielectric layers than over the metal-semiconductor alloy regions 84.

In FIGS. 10A and 10B, a conductive material 94 is formed in the source/drain contact openings 82 and on the contact liner layer 88 to electrically couple to the upper epitaxial source/drain regions 62U and/or the lower epitaxial source/drain regions 62L. The source/drain contacts 96 comprise the contact liner layer 88 and the conductive material 94. The conductive material 94 may be a metal such as ruthenium, tungsten, molybdenum, cobalt, copper, a copper alloy, silver, gold, aluminum, nickel, combinations thereof, or the like and may be formed by a plating process, PVD, CVD, ALD, or the like. A removal process may be performed to remove excess material from the top surfaces of the gate spacers 44 and the second ILD 72. The remaining contact liner layer 88 and conductive material 94 form the source/drain contacts 96 in the source/drain contact openings 82. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Formation of the contact liner layer 88 as described above improves the processes for depositing the conductive material 94 in the source/drain contact openings 82. As discussed above, the lower source/drain contact openings 82L may have high aspect ratios such that deposition of the conductive material 94 may be prone to pinching or void formation. In addition, the aspect ratios increase after formation of the contact liner layer 88 by further narrowing the remainders of the source/drain contact openings 82. However, the contact liner layer 88 formed in accordance with the disclosed embodiments is a thin graphene sheet which is substantially uniform and flat. This allows the conductive material 94 to diffuse along the contact liner layer 88 to reach lower portions of the source/drain contact openings 82 with less attachment and buildup along upper portions of the sidewalls. In addition, when portions of the conductive material 94 are attached to the contact liner layer 88, the substantial uniformity and flatness ensure that these attached portions of the conductive material 94 remain in place and are less likely to slide.

As discussed above, the aspect ratios of the lower source/drain contact openings 82L may be as high as ranging from about 8 to about 15. In addition, the aspect ratios may increase by 7% to 33% upon formation of the contact liner layer 88 which may have a thickness of about 5 Å (e.g., decreasing the width of the source/drain contact openings 84 by about 1 nm). For example, a lower source/drain contact opening 82L having a width of about 15 nm may decrease to about 14 nm after formation of the contact liner layer 88, which may increase the range of aspect ratios of 8 to 15 to aspect ratios of about 8.5 to about 16. In addition, a lower source/drain contact opening 82L having a width of about 4 nm may decrease to about 3 nm after formation of the contact liner layer 88, which may increase the range of aspect ratios of 8 to 15 to aspect ratios of about 10.5 to about 20. It should be appreciated that a thicker contact liner layer 88 would cause greater increases to the aspect ratio, which would increase the risk of pinching and/or forming voids during deposition of the conductive material 94.

In some embodiments (not specifically illustrated), the conductive material 94 may be deposited over the contact liner precursor 86 before performing the treatment process (e.g., the FVP annealing process) on the contact liner precursor 86. In such embodiments, the annealing process may be performed before or after the removal process to remove excess material and level the conductive material 94.

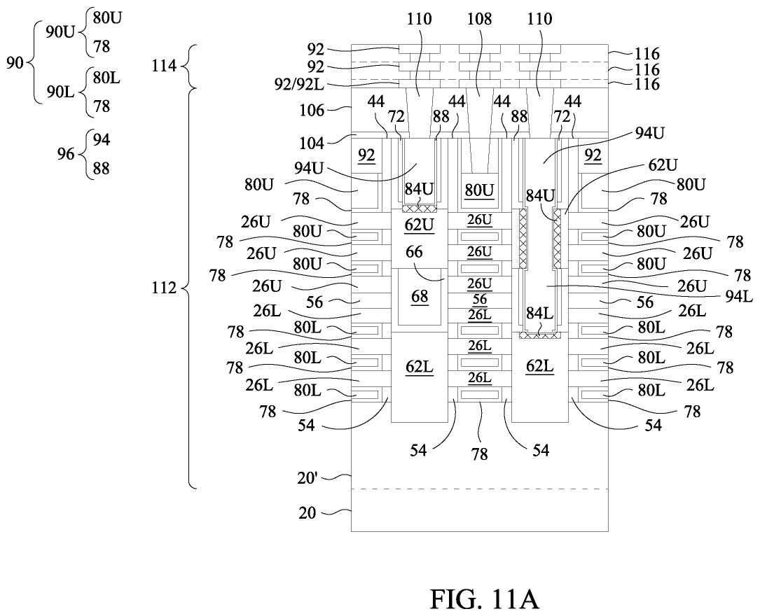

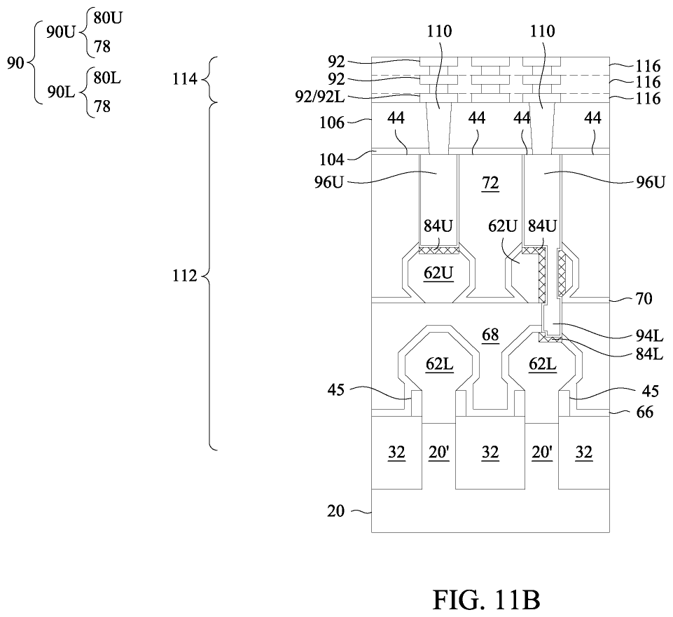

In FIGS. 11A and 11B, an ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 62L may be made through a backside of the device layer 112 (e.g., a side opposite to the front-side interconnect structure 114).

In FIG. 12, contacts to the lower gate stacks 90L and the lower epitaxial source/drain regions 62L may be made through a backside of the device layer 122 (e.g., a side opposite to the front-side interconnect structure 128), in accordance with various embodiments. For example, the device layer 122 is illustrated as being between the front-side interconnect structure 128 and a backside interconnect structure 134. The backside interconnect structure 134 may be substantially similar to the front-side interconnect structure 128 as described above. Note that like reference numerals indicate like elements formed by like processes as described above.

Contact vias 130 having contact spacers 132 disposed on sidewalls thereof are formed to extend through at least partially through the device layer 122. The contact vias 130 and the contact spacers 132 may be formed of like materials and like processes as the upper and lower source/drain vias 110. For example, openings may be formed by a combination of photolithography and etching processes. The contact spacers 132 may comprise silicon oxide, silicon nitride, silicon oxynitride, silicon oxycarbonitride, combinations thereof, or the like and may be formed by conformally depositing an insulating material layer (not explicitly illustrated) by CVD, ALD, or the like. Then, lateral portions of the insulating material layer may be etched away by an anisotropic etching process, such as a plasma-based dry etch, thereby forming the contact spacers 132. Conductive material is then formed in the opening and may include cobalt, tungsten, copper, a copper alloy, silver, gold, aluminum, nickel, or the like. A planarization process, such as a CMP, may be performed to remove excess material from the top surface of the second ILD 72.

As illustrated, the contact vias 130 and the contact spacers 132 may be formed through the first CESL 66, the first ILD 68, the second CESL 70 and the second ILD 72 prior to forming the ESL 104 and the third ILD 106. The contact vias 130 may be electrically connected to the backside interconnect structure 134, and the contact vias 130 may also be electrically connected to front-side interconnect structure 128 (e.g., through the upper source/drain contacts 120). In this manner, interconnection between the front-side interconnect structure 128 and the backside interconnect structure 134 may be achieved.

As further illustrated, some of the source/drain contacts 96 may be coupled to the contact vias 130. Formation of the source/drain contacts 96 may be performed similarly as described above in connection with FIGS. 6A through 10B. In some embodiments, the third ILD 106 is formed before or as part of formation of the source/drain contacts 96. Moreover, the third ILD 106 may comprise a plurality of layers to facilitate multiple patterning and etching steps in order for the source/drain contacts 96 to be coupled to the contact vias 130 and/or the source/drain regions 62. As such, the third ILD 106 and the ESL 104 may collectively comprise ESL 104A, third ILD 106A, ESL 104B, and third ILD 106B. In addition, as discussed above, a widening process may be utilized to widen upper portions of the source/drain contact openings 82 (see FIGS. 6A and 6B). The over-etching of the upper portions may be used to decrease the aspect ratio for the upper portions of the source/drain contact openings 82, which provides further improvement to the gap-fill processes (see FIGS. 8A through 10B).

FIGS. 13 through 16 illustrate additional embodiments for forming the conductive material 94 over the contact liner layer 88 in the source/drain contact openings 82. Note that these embodiments may be utilized in combination with any other embodiments described above, where appropriate and suitable.

In FIG. 13, a first portions of the conductive material 94 are formed in the source/drain contact openings 82. As illustrated, a first portion of the upper conductive material 94U is formed in the upper source/drain contact opening 82U, and a first portion of the lower conductive material 94L is formed in the lower source/drain contact opening 82L. In some embodiments, the first portion of the lower conductive material 94L may form one or more voids 94V due to the high aspect ratio of the lower source/drain contact opening 82L.

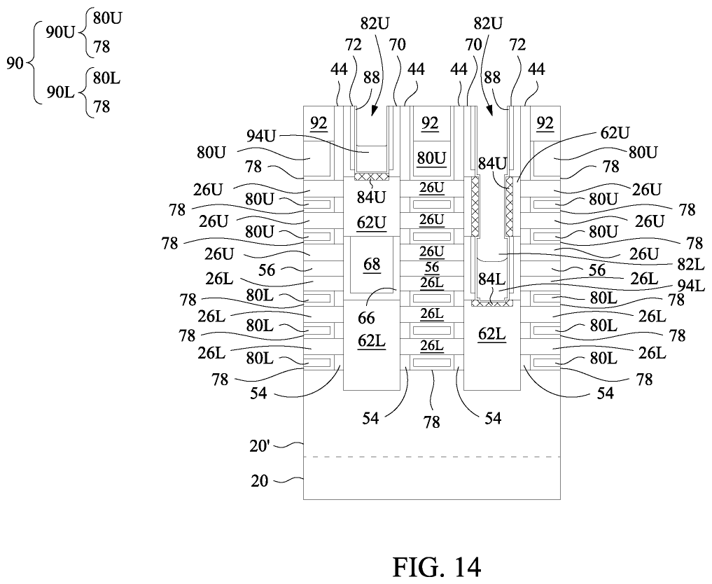

In FIG. 14, an etch-back process is performed to remove some of the first portions of the conductive material 94. In particular, the etch-back process is performed until the voids 94V are no longer enclosed in the conductive material 94 (e.g., the lower conductive material 94L). The etch-back process may comprise an anisotropic etch, an isotropic etch, or a combination thereof.

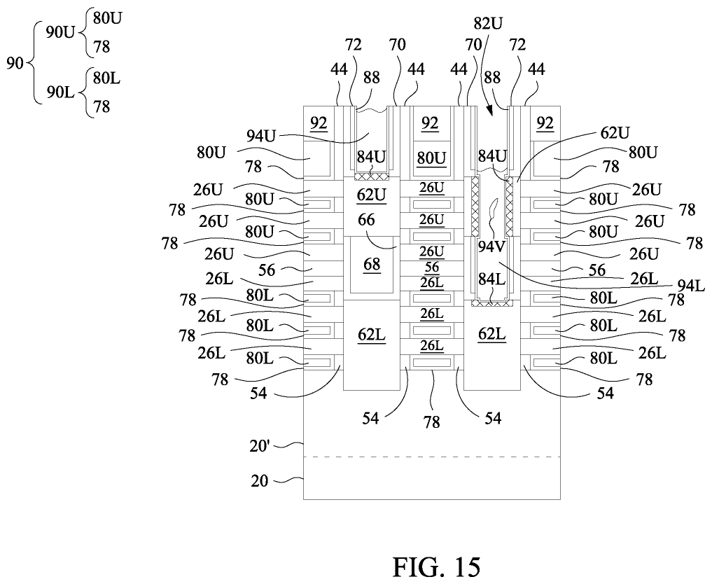

In FIG. 15, second portions of the conductive material 94 are formed over the etched first portions of the conductive material 94. As illustrated, a second portion of the upper conductive material 94U is formed to further fill the upper source/drain contact opening 82U, and a second portion of the lower conductive material 94L is formed to fill the lower source/drain contact opening 82L. In some embodiments, the second portion of the lower conductive material 94L may form one or more additional voids 94V due to the high aspect ratio of the lower source/drain contact openings 82L.

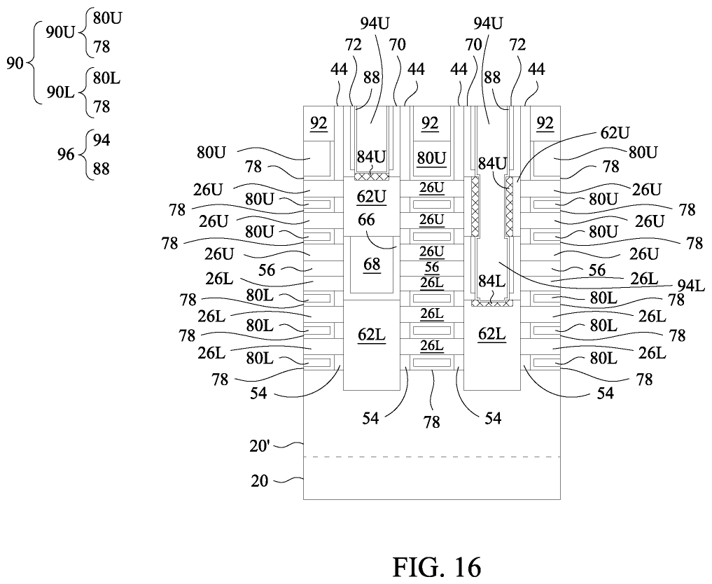

In FIG. 16, another etch-back process may be performed to remove the additional voids 94V, and the source/drain contact openings 82 may be filled with third portions of the conductive material 94. In some embodiments, the steps of depositing the conductive material 94 and etching back the conductive material 94 may be performed any suitable number of times to ensure the conductive material 94 is substantially free of voids 94V. For example, some embodiments may utilize one etch-back step, and other embodiments may utilize more than two etch-back steps. After remainders of the source/drain contact openings 82 are filled and free of voids 94V, the removal process and other processing steps may be performed, similarly as described above.

Various advantages are achieved. Some contact openings, such as lower source/drain contact openings 82L which lead to lower source/drain regions 62L of stacking transistors may have high aspect ratios. In particular, formation of the lower source/drain contacts 96L may benefit from the embodiments disclosed herein. For example, the contact liner layer 88 may be deposited as polycyclic aromatic hydrocarbons (PAHs) and treated to be converted into an ultra thin graphene sheet. The contact liner layer 88 may be less than or equal to 5 Å. As a result, the aspect ratio of the lower source/drain contact openings 82L increases by only a small amount after formation of the contact liner layer 88. This allows the conductive material 94 to be deposited with substantially zero voids (or very few voids). The semiconductor devices which utilize these transistors may therefore operator with improved performance and greater reliability.

In an embodiment, a method includes patterning a first opening through a first dielectric layer to expose a first source/drain region; forming a first silicide region on the first source/drain region; depositing a first plurality of polycyclic aromatic hydrocarbons along surfaces of the first opening; performing an annealing process to convert the first plurality of polycyclic aromatic hydrocarbons into a first graphene layer; and filling a remainder of the first opening with a first metal material. In another embodiment, the method further includes forming a second opening through the first dielectric layer, a second source/drain region, and a third dielectric layer to expose a third source/drain region, wherein in a top-down view the second source/drain region overlaps the third source/drain region. In another embodiment, forming the first silicide region comprises: forming a second silicide region on the second source/drain region; and forming a third silicide region on the third source/drain region. In another embodiment, the method further includes depositing a second plurality of polycyclic aromatic hydrocarbons along surfaces of the second opening; performing the annealing process to convert the second plurality of polycyclic aromatic hydrocarbons into a second graphene layer; and filling a remainder of the second opening with a second metal material. In another embodiment, filling the remainder of the second opening with the second metal material comprises: depositing a first portion of the second metal material into the second opening; performing an etch process to remove some of the first portion of the second metal material; and after performing the etch process, depositing a second portion of the second metal material into the second opening. In another embodiment, an interface between the first graphene layer and the first silicide region is free of chemical bonds. In another embodiment, before filling the remainder of the first opening, the first plurality of polycyclic aromatic hydrocarbons adhere to the first silicide region by van der Waals forces. In another embodiment, filling the remainder of the first opening with the first metal material is performed before performing the annealing process to convert the first plurality of polycyclic aromatic hydrocarbons into the first graphene layer.

In an embodiment, a method includes forming a first opening through a plurality of layers to expose a first source/drain region, the plurality of layers comprising: a first dielectric layer disposed over the first source/drain region; a second source/drain region disposed over the first dielectric layer; and a second dielectric layer disposed over the second source/drain region; forming a first metal-semiconductor alloy on a surface of the first source/drain region; forming a second metal-semiconductor alloy on a surface of the second source/drain region; performing a thermal evaporation deposition to deposit a first material in the first opening, the first material comprising a plurality of discontinuous sheets; performing an annealing process to convert the first material to a second material, the second material comprising a continuous sheet; and depositing a conductive material to fill the first opening. In another embodiment, the first material comprises polycyclic aromatic hydrocarbons. In another embodiment, the second material comprises graphene. In another embodiment, the second material has a thickness of less than or equal to 5 Å. In another embodiment, the annealing process comprises a flash vacuum pyrolysis. In another embodiment, the conductive material comprises ruthenium.

In an embodiment, a semiconductor device includes a first source/drain region; a first silicide region on the first source/drain region; first nanostructures adjacent to the first source/drain region; a second source/drain region overlapping the first source/drain region; a second silicide region on the second source/drain region; a contact plug extending through the second source/drain region to the first source/drain region, the contact plug comprising: a contact liner layer comprising a polycyclic aromatic hydrocarbon; and a metal material; second nanostructures adjacent to the second source/drain region; a first gate structure around the first nanostructures; and a second gate structure overlapping the first gate structure and around the second nanostructures. In another embodiment, the contact liner layer comprises a graphene sheet. In another embodiment, the contact liner layer has a thickness of less than or equal to 5 Å. In another embodiment, the contact liner layer comprises a continuous sheet extending between the first silicide region to the second silicide region. In another embodiment, the metal material comprises ruthenium. In another embodiment, the semiconductor device further includes a third source/drain region adjacent to the second nanostructures; and an additional contact plug extending to the third source/drain region, the additional contact plug comprising: an additional contact liner layer comprising the polycyclic aromatic hydrocarbon; and an additional metal material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first transistor over a substrate, the first transistor having a first source/drain region;
forming a second transistor over the first transistor, the second transistor having a second source/drain region, the second transistor being of an opposite conductivity type from the first transistor;
forming a contact opening extending through the second source/drain region to expose the first source/drain region;
depositing a carbon-based liner precursor along surfaces of the contact opening;
forming a carbon-based liner in the contact opening from the carbon-based liner precursor, wherein forming the carbon-based liner comprises annealing the carbon-based liner precursor; and
depositing a conductive fill material in the contact opening.

2. The method of claim 1, wherein the carbon-based liner precursor comprises a plurality of polycyclic aromatic hydrocarbons (PAHs), and wherein the carbon-based liner comprises graphene.

3. The method of claim 2, wherein the plurality of PAHs comprises one or more of anthracene, pyrene, perylene, coronene, ovalene, and benzocoronene.

4. The method of claim 1, wherein the carbon-based liner has a greater conductivity than the carbon-based liner precursor.

5. The method of claim 1, wherein the carbon-based liner has a thickness ranging from about 3 Å to about 5 Å.

6. The method of claim 1, wherein annealing the carbon-based liner precursor comprises a flash vacuum pyrolysis anneal at a temperature between about 300 °C and about 1100 °C.

7. The method of claim 1, further comprising, before depositing the carbon-based liner precursor, forming silicide or germanide regions along exposed surfaces of the first source/drain region and the second source/drain region.

8. The method of claim 1, wherein the contact opening has an aspect ratio between about 8 and about 15.

9. The method of claim 1, wherein forming the contact opening comprises:
etching an initial opening extending through the second source/drain region and into the first source/drain region; and
widening an upper portion of the initial opening to form the contact opening, wherein the contact opening has a first aspect ratio at the upper portion and a second aspect ratio at a lower portion, the second aspect ratio being greater than the first aspect ratio.

10. A method comprising:
forming a first interlayer dielectric over a first epitaxial region;
forming a second epitaxial region over the first interlayer dielectric and directly above the first epitaxial region;
forming a second interlayer dielectric over the second epitaxial region;
forming a contact opening through the second interlayer dielectric, the second epitaxial region, and the first interlayer dielectric to expose the first epitaxial region;
depositing a plurality of polycyclic aromatic hydrocarbons (PAHs) in the contact opening;
converting the plurality of PAHs into a graphene liner along surfaces of the contact opening; and
depositing a conductive fill material in the contact opening, wherein depositing the conductive fill material is performed either before or after converting the plurality of PAHs into the graphene liner.

11. The method of claim 10, wherein converting the plurality of PAHs into the graphene liner comprises a flash vacuum pyrolysis anneal.

12. The method of claim 10, wherein the first epitaxial region comprises a first source/drain region adjacent to a first channel region and a first gate electrode of a first transistor, wherein the second epitaxial region comprises a second source/drain region adjacent to a second channel region and a second gate electrode of a second transistor.

13. The method of claim 10, wherein a third epitaxial region is formed simultaneously with the second epitaxial region, the method further comprising:
forming an additional contact opening through the second interlayer dielectric to expose the third epitaxial region;
depositing an additional plurality of PAHs in the additional contact opening;
converting the additional plurality of PAHs into an additional graphene liner along surfaces of the additional contact opening; and
depositing an additional conductive fill material in the additional contact opening.

14. The method of claim 10, wherein converting the plurality of PAHs into the graphene liner is performed prior to depositing the conductive fill material.

15. The method of claim 10, wherein depositing the conductive fill material is performed prior to converting the plurality of PAHs into the graphene liner.

16. A method comprising:
forming first source/drain regions adjacent to first channel regions;
forming a first interlayer dielectric over the first source/drain regions;
forming second source/drain regions over the first interlayer dielectric and adjacent to second channel regions;
forming a second interlayer dielectric over the second source/drain regions;
forming a first contact opening to expose a first one of the first source/drain regions and a first one of the second source/drain regions;
forming a second contact opening to expose a second one of the second source/drain regions;
depositing a first liner in the first contact opening and in the second contact opening, the first liner comprising polycyclic aromatic hydrocarbons (PAHs);
annealing the first liner to form a second liner, the second liner comprising at least a majority of the PAHs bonded to one another;
filling a remainder of the first contact opening and a remainder of the second contact opening with a conductive material; and
planarizing the conductive material and the second liner to form a first contact plug in the first contact opening and a second contact plug in the second contact opening.

17. The method of claim 16, further comprising forming a first metal-semiconductor alloy region at a surface of the first one of the first source/drain regions and a second metal-semiconductor alloy region at a surface of the first one of the second source/drain regions, and wherein the first metal-semiconductor alloy region and the second metal-semiconductor alloy region are formed before depositing the first liner.

18. The method of claim 16, wherein the second liner has a thickness of less than or equal to about 5 Å.

19. The method of claim 16, wherein depositing the first liner comprises a thermal evaporation deposition process performed at a temperature ranging from about 300 °C to about 400 °C, and wherein the annealing comprises a flash vacuum pyrolysis annealing process performed at a temperature ranging from about 300 °C to about 1100 °C, at a pressure ranging from about 1×10⁻⁴ Torr to about 5 Torr, and for a duration ranging from about 0.1 seconds to about 5 seconds.

20. The method of claim 16, wherein filling the remainder of the first contact opening comprises:
depositing a first portion of the conductive material in the first contact opening;
performing an etch-back process on the first portion of the conductive material to expose voids formed therein; and
depositing a second portion of the conductive material in the first contact opening over the first portion of the conductive material.
